(19) United States
(12) Patent Application Publication
(10) Pub. No.: US 2017/0138120 A1
(43) Pub. Date: May 18, 2017

(54) OPTICAL SWITCHING DEVICE AND BUILDING MATERIAL

(71) Applicant: PANASONIC INTELLECTUAL PROPERTY MANAGEMENT CO., LTD., 540-6207 (JP)

(72) Inventor: Yuko SUZUKA, Osaka (JP)

(73) Assignee: PANASONIC INTELLECTUAL PROPERTY MANAGEMENT CO., LTD., Osaka (JP)

(21) Appl. No.: 15/318,135

(22) PCT Filed: Jun. 24, 2015
(86) PCT No.: PCT/JP2015/003154

§ 371 Date: Dec. 12, 2016

(30) Foreign Application Priority Data
Jul. 11, 2014 (JP) 2014-142799

(51) Int. Cl. E06B 9/24; G02F 1/1343; G02F 1/1335; H01L 51/52; G02F 1/1334; G02F 1/1345; H01L 27/32

(52) U.S. Cl. CPC E06B 9/24; G02F 1/1345; G02F 1/1343; H01L 27/3202; H01L 27/3204; H01L 51/5203; G02F 1/1334; G02F 1/1336; H01L 51/5206; H01L 51/5234; H01L 2251/301; H01L 2251/308; H01L 51/5253; G02F 1/163

(57) ABSTRACT

An optical switching device includes: a plurality of optically variable units that are variable in a degree of optical transparency according to electric power; and a plurality of power supply terminals that supply electric power to any of the plurality of optically variable units. The plurality of optically variable units are arranged in a thickness direction. Each of the plurality of optically variable units has a pair of electrodes. Each of the pair of electrodes in at least one of the plurality of optically variable units is connected to the plurality of power supply terminals. The plurality of power supply terminals supply electric power in which at least one of current and voltage is controlled in a plurality of levels.

### TECHNICAL FIELD

An optical switching device and a building material are disclosed. In particular, an optical switching device and building material capable of changing the degree of optical transparency according to electric power are disclosed.

### BACKGROUND ART

Members that change in optical transparency according to electricity are gaining attention in recent years. Members that change in optical transparency can be used in building materials such as windows. For example, a transparent organic EL element has optical transparency that changes between the light emitting state and the non-light emitting state. An organic EL element that changes in optical property is, for example, described in Patent Literature (PTL) 1. In PTL 1, an optical layer for changing the traveling direction of light is provided to change the optical property of the organic EL element.

### CITATION LIST

### Patent Literature

PTL 1: Japanese Unexamined Patent Application Publication No. 2013-201009

### SUMMARY OF THE INVENTION

### Technical Problem

A member that changes in optical transparency is expected to have improved optical property by providing variations in the change between the transparent state and the non-transparent state.

The present disclosure has an object of providing an optical switching device and building material having excellent optical property.

### Solutions to Problem

An optical switching device according to an aspect of the present disclosure includes: a plurality of optically variable units that are planar and are variable in a degree of optical transparency according to electric power; and a plurality of power supply terminals that supply electric power to any of the plurality of optically variable units, wherein the plurality of optically variable units are arranged in a thickness direction, each of the plurality of optically variable units has a pair of electrodes, each of the pair of electrodes in at least one of the plurality of optically variable units is connected to the plurality of power supply terminals, and the plurality of power supply terminals supply electric power in which at least one of current and voltage is controlled in a plurality of levels.

A building material according to an aspect of the present disclosure includes: the optical switching device; and wiring.

### Advantageous Effects of Invention

The optical switching device according to the present disclosure has the electrodes each connected to the plurality of power supply terminals. Such an optical switching device has excellent optical property as the optical state can be changed in a plane with distribution. The building material according to the present disclosure includes the optical switching device, and so has excellent optical property.

### BRIEF DESCRIPTION OF DRAWINGS

FIG. 1 is a sectional view schematically illustrating an example of an optical switching device.

FIG. 2 is a sectional view schematically illustrating an example of an optical switching device.

FIG. 3 is a sectional view schematically illustrating an example of an optical switching device.

FIG. 4 illustrates an example of electrodes, where A is a plan view schematically illustrating an electrode and B is a perspective view schematically illustrating a pair of electrodes.

FIG. 5 illustrates an example of an optically variable unit, where A is a graph schematically illustrating the relationship between the drive voltage and the light transmittance in the optically variable unit and B is a plan view schematically illustrating the optically variable unit.

FIG. 6 is a plan view illustrating an example of how the optical state of the optical switching device changes in a plane, where A illustrates an opaque state, B illustrates a non-uniform optical state, and C illustrates a transparent state.

FIG. 7 is a plan view schematically illustrating an example of a pair of electrodes, where A illustrates one of the pair of electrodes and B illustrates the other one of the pair of electrodes.

FIG. 8 is a plan view schematically illustrating an example of a pair of electrodes, where A illustrates one of the pair of electrodes, B illustrates the other one of the pair of electrodes, and C illustrates a partial cross section of each electrode.

FIG. 9 is a plan view schematically illustrating an example of a pair of electrodes, where A illustrates one of the pair of electrodes, B illustrates the other one of the pair of electrodes, and C illustrates a partial cross section of each electrode.

FIG. 10 is a plan view illustrating an example of how the optical state of the optical switching device changes in a plane, where A illustrates a transparent state, B illustrates a non-uniform optical state (pattern forming state), and C illustrates an opaque state.

FIG. 11 is a view schematically illustrating the functioning states of a plurality of optically variable units in the optical switching device, where A illustrates the state where light scattering is performed, B illustrates the state where light is emitted, C illustrates the state where light reflection is performed, D illustrates the state where light absorption is performed, E illustrates the state where light scattering is performed and light is emitted, F illustrates the state where light scattering and light reflection are performed, G illustrates the state where light scattering and light absorption are performed, H illustrates the state where light reflection is performed and light is emitted, I illustrates the state where light absorption is performed and light is emitted, J illustrates the state where light reflection and light absorption are performed, K illustrates the state where light scattering and light reflection are performed and light is emitted, L illustrates the state where light scattering and light absorption are performed and light is emitted, M illustrates the state where light scattering, light reflection, and light absorption are performed, N illustrates the state where light reflection and light absorption are performed and light is emitted, P illustrates the state where light scattering, light reflection, and light absorption are performed and light is emitted, and Q illustrates the state where light scattering, light reflection, and light absorption are all not performed and light is not emitted.

FIG. 12 is a view illustrating an example of a building material including the optical switching device.

### DESCRIPTION OF EXEMPLARY EMBODIMENT

### Embodiment

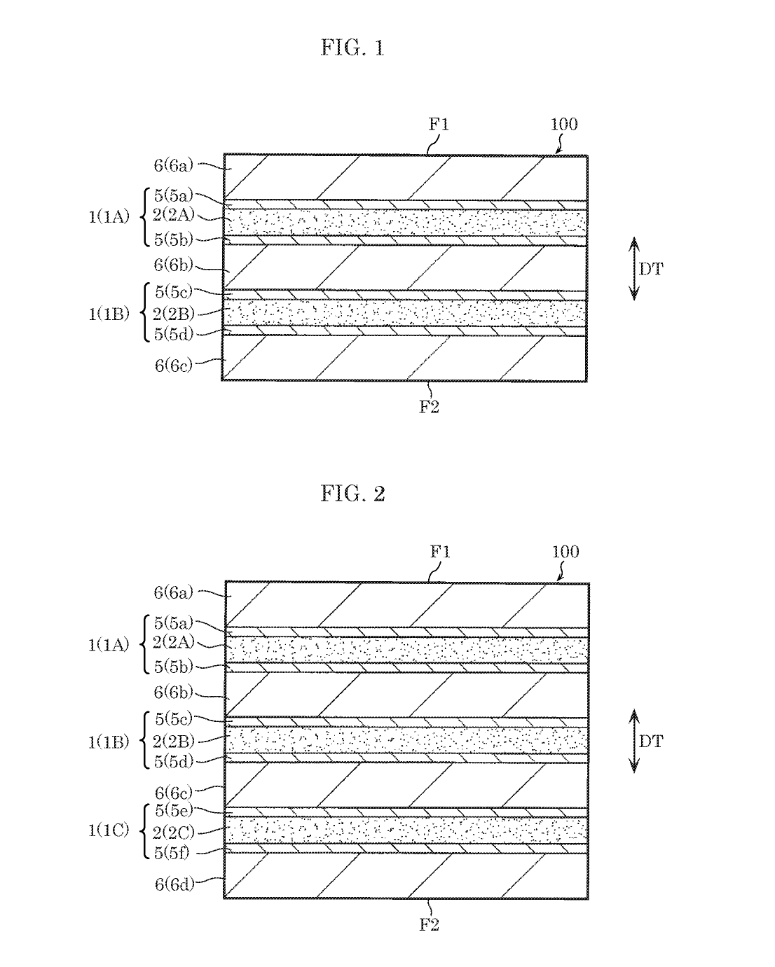

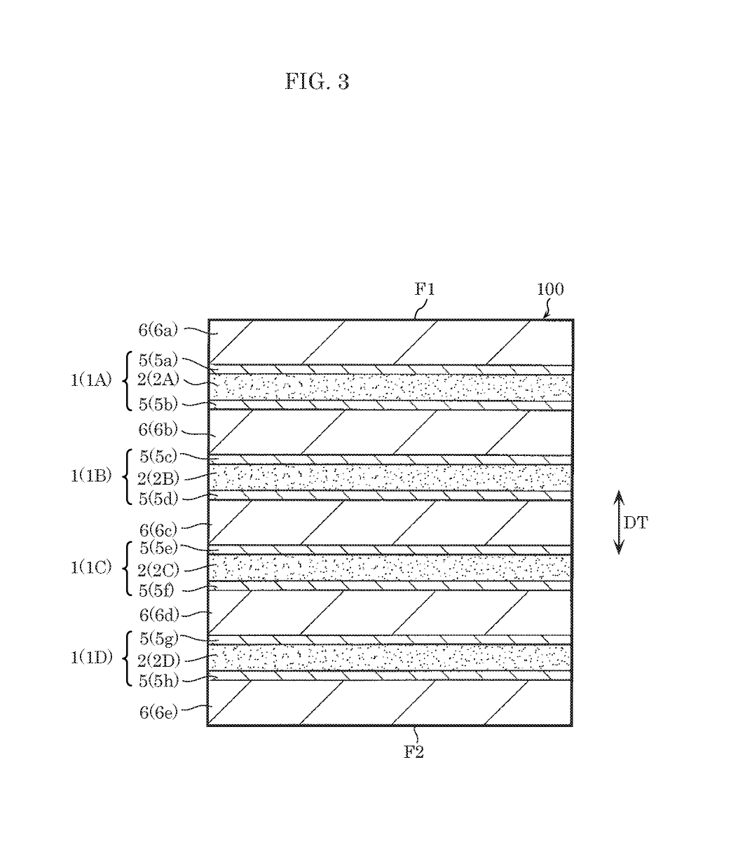

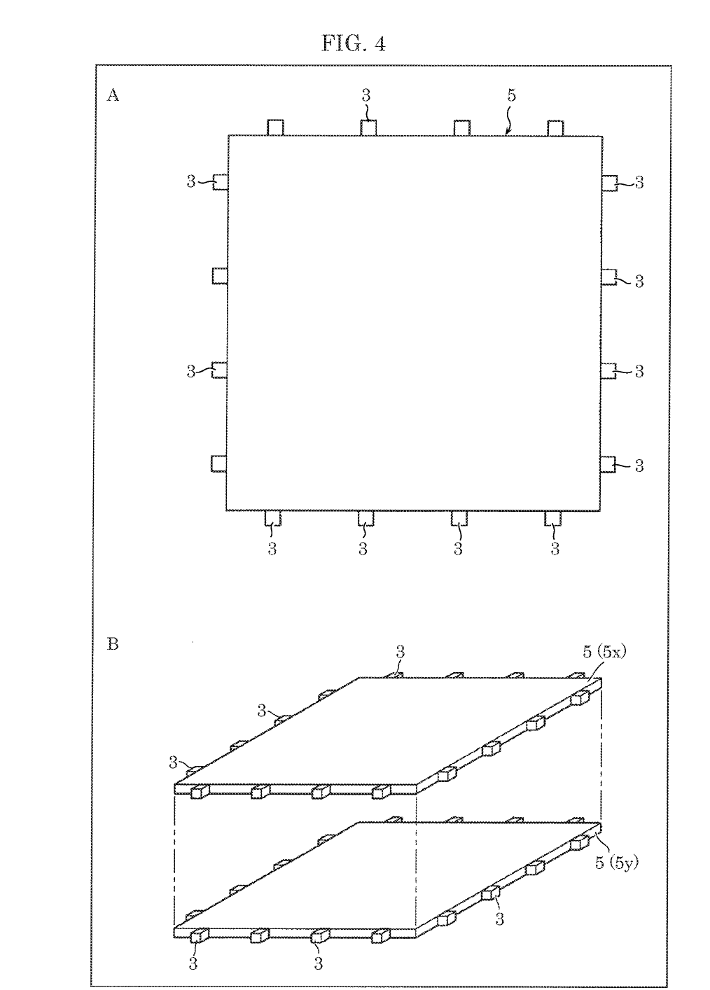

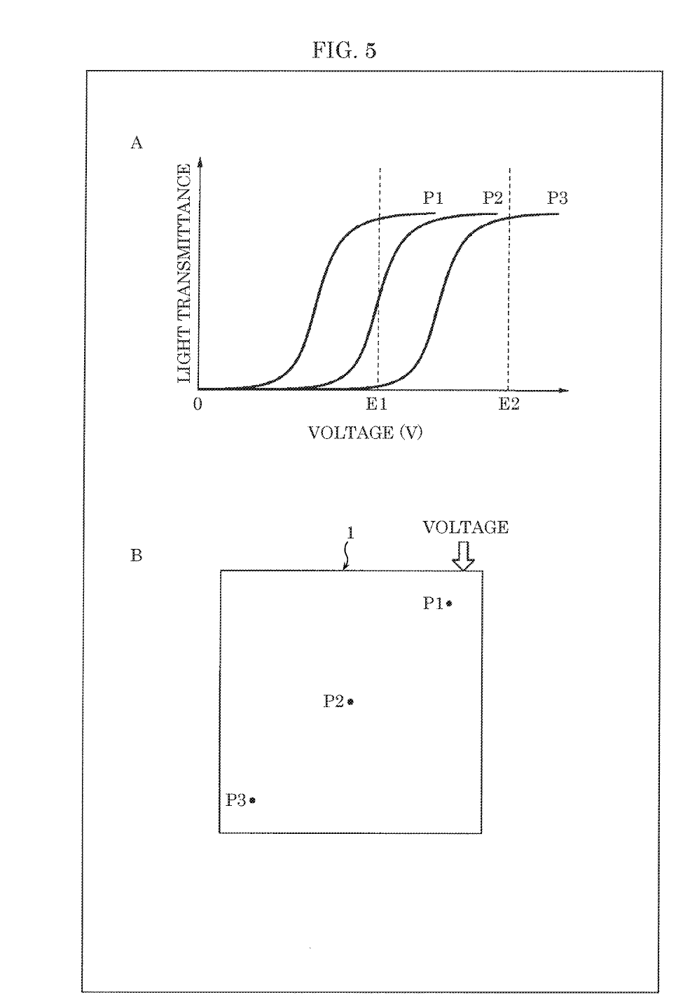

An optical switching device is disclosed below. FIG. 1 illustrates an example of optical switching device 100. FIG. 2 illustrates another example of optical switching device 100. FIG. 3 illustrates still another example of optical switching device 100. FIG. 4 illustrates an example of electrodes 5 in optical switching device 100.

Optical switching device 100 includes plurality of optically variable units 1. In the example in FIG. 1, plurality of optically variable units 1 are first optically variable unit. 1A and second optically variable unit 1B. In the example in FIG. 2, plurality of optically variable units 1 are first optically variable unit 1A, second optically variable unit 1B, and third optically variable unit 1C. In the example in FIG. 3, plurality of optically variable units 1 are first optically variable unit 1A, second optically variable unit 1B, third optically variable unit 1C, and fourth optically variable unit 1D. Optically variable unit 1 is planar. Optically variable unit 1 is variable in the degree of optical transparency according to electric power. Plurality of optically variable units 1 are arranged in the thickness direction. The inclusion of plurality of optically variable units 1 improves the optical property.

The thickness direction is the direction of the thickness of optical switching device 100. In FIGS. 1 to 3, the thickness direction is designated by arrow DT. The thickness direction may be the direction perpendicular to the surface of substrate 6. In FIGS. 1 to 3, each layer of optical switching device 100 can be regarded as extending in the direction perpendicular to the thickness direction. The term “planar view” means a view along the direction (thickness direction DT) perpendicular to the surface of substrate 6.

Each of plurality of optically variable units 1 includes pair of electrodes 5. Pair of electrodes 5 are two electrodes electrically paired with each other. Optical switching device 100 includes plurality of power supply terminals 3 for supplying electric power to optically variable unit 1. In optical switching device 100, each of pair of electrodes 5 in at least one of plurality of optically variable units 1 is connected to plurality of power supply terminals 3. A in FIG. 4 illustrates plurality of power supply terminals 3 connected to one electrode 5. As illustrated in B in FIG. 4, two such electrodes 5 may constitute pair electrodes 5. Such pair of electrodes 5 may be pair of electrodes 5 in any optically variable unit 1.

Plurality of power supply terminals 3 supply electric power in which at least one of current and voltage is controlled in a plurality of levels. This enables controlling the optical state in separate parts in the plane. For example, it is possible to make the optical state of one part the plane high and the optical state of another part in the plane low. In some cases, such part with high optical state and part with low optical state may form a pattern. The optical property of optical switching device 100 is improved in this way. The optical state mentioned here means any of the states of transparency, light emission, light scattering, light reflection, and light absorption.

Optical switching device 100 is sheetlike. Optical switching device 100 may be panel-shaped. Optical switching device 100 switches the state of light.

Optical switching device 100 has first surface F1 and second surface F2 opposite to first surface F1. First surface F1 and second surface F2 are outer surfaces. These surfaces may be exposed. Alternatively, first surface F1 and second surface F2 may each be covered with another transparent sheetlike member.

The surfaces of optical switching device 100 include flat and curved surfaces. The surfaces may all be flat surfaces. Alternatively, the surfaces may all be curved surfaces. For example, the surfaces may be arc-like. Alternatively, the surfaces may include both flat and curved surfaces.

FIGS. 1 to 3 each illustrate an example of optical switching device 100, and the optical switching device is not limited to such. FIGS. 1 to 3 and the other drawings schematically illustrate optical switching device 100 and each component in optical switching device 100, which may be different from the actual dimensional relationships and the like. In the drawings, components given the same reference sign are the same components, and the description on any of such components is commonly applicable, unless otherwise stated.

Plurality of optically variable units 1 are supported by plurality of substrates 6. Each optically variable unit 1 is located between pair of substrates 6. Optically variable unit 1 is thus protected. Optically variable unit 1, by being supported by substrates 6, can be manufactured easily and stabilized.

In FIGS. 1 to 3, plurality of substrates 6 are designated as substrates 6a, 6b, 6c, 6d, and 6e in order from the first surface F1 side, for the sake of convenience.

Optical switching device 100 may have plurality of substrates 6. Plurality of substrates 6 have optical transparency. Such optical switching device 100 has high optical property. Substrates 6 can function as substrates for supporting the layers of optical switching device 100. Substrates 6 can function as substrates for sealing the layers of optical switching device 100. Plurality of substrates 6 are arranged in the thickness direction.

Optical switching device 100 may have plurality of optically variable units 1 between two substrates 6 located outside from among plurality of substrates 6. Plurality of optically variable units 1 can thus be protected by substrates 6.

Substrate 6 may be a glass substrate, a resin substrate, or the like. In the case where substrate 6 is a glass substrate, optical switching device 100 has excellent optical property as glass has high transparency. In addition, since glass has low moisture permeability, moisture can be kept from entering the sealed region. Further, since glass may have ultraviolet absorptivity, device degradation can be prevented. Examples of glass include soda glass, alkali-free glass, and high refractive index glass. Thin-film glass may be used as substrate 6. In this case, optical switching device 100 not only has high transparency and high dampproofness but also is flexible. In the case where substrate 6 is a resin substrate, optical switching device 100 is safe as it is prevented from scattering upon breaking because a resin resists fracture. In addition, the use of a resin substrate can make optical switching device 100 flexible. The resin substrate may be filmlike. Examples of the resin include polyethylene terephthalate (PET) and polyethylene naphthalate (PEN).

Two substrates 6 located outside from among plurality of substrates 6 may be glass substrates. Such optical switching device 100 has excellent optical property. Plurality of substrates 6 may all be glass substrates. In this case, the optical condition can be controlled easily to enhance the optical property. Any one or more of inner substrates 6 may be resin substrates. Such optical switching device 100 is safe, as it is prevented from scattering upon breaking. The surface of substrate 6 may be coated with any one or more of an antifouling material, an ultraviolet screening material, an ultraviolet absorbing material, and a dampproof material. This enhances protection.

Electrode 5 may be a transparent conductive layer. The material of the transparent conductive layer may be a transparent metal oxide, a conductive particle-containing resin, a metal thin film, or the like. Electrode 5 may be made of a conductive material suitable for each location. The material of electrode 5 having optical transparency is, for example, a transparent metal oxide such as ITO or IZO. Electrode 5 made of a transparent metal oxide is suitably used as electrode 5 in optically variable unit 1. Electrode 5 may be a layer containing silver nanowires or a transparent metal layer of thin-film silver or the like. Electrode 5 may be formed by stacking a transparent metal oxide layer and a metal layer. Electrode 5 may be a transparent conductive layer provided with wiring for electrical assistance. Electrode 5 may have a thermal insulation effect. This can improve thermal insulation performance. A dampproof layer may be formed between substrate 6 and electrode 5. The dampproof layer keeps moisture from entering into optical switching device 100, thus suppressing the degradation of optical switching device 100.

Pair of electrodes 5 are two electrodes 5 electrically paired with each other. One of pair of electrodes 5 forms an anode, and the other one of pair of electrodes 5 forms a cathode. One of pair of electrodes 5 is located on the first surface F1 side, and the other one of pair of electrodes 5 on the second surface F2 side.

Plurality of electrodes 5 may be electrically connectable to a power source. Optical switching device 100 may have electrode pads, an electrical connection electrically combining the electrode pads, etc., for connection to the power source. The electrical connection may be a plug or the like.

In FIGS. 1 to 3, plurality of electrodes 5 are designated as electrodes 5a, 5b, 5c, 5d, 5e, 5f, 5g, and 5h in order from the first surface F1 side, for the sake of convenience.

Each optically variable unit 1 includes optically variable layer 2. Optically variable layer 2 is located between pair of electrodes 5. Optically variable layer 2 is supplied with electric power via pair of electrodes 5, and varies in the degree of optical transparency. Pair of electrodes 5 function as electrodes for driving optically variable layer 2. Optically variable layer 2 in first optically variable unit 1A is defined as first optically variable layer 2A. Likewise, respective optically variable layers 2 in second optically variable unit 1B to fourth optically variable unit 1D are defined as second optically variable layer 2B, third optically variable layer 2C, and fourth optically variable layer 2D.

Plurality of optically variable units 1 are each selected from a planar light emitting unit, a light scattering variable unit, a light reflection variable unit, and a light absorption variable unit. The planar light emitting unit may be an element that emits light planarly according to supplied electric power. The light scattering variable unit may be an element variable in the degree of light scattering according to electric power. The light reflection variable unit may be an element variable in the degree of light reflection according to electric power. The light absorption variable unit may be an element variable in the degree of light absorption according to electric power.

Plurality of optically variable units 1 may include the planar light emitting unit. The planar light emitting unit, is capable of emitting light planarly. The planar light emitting unit may be an organic electroluminescent element (organic EL element). Thin and large-area light emission can be obtained in this way. The planar light emitting unit may be transparent.

In the case where optically variable unit 1 is an organic EL element, optically variable layer 2 may be an organic light emitting layer. The organic EL element is an element having the structure in which the organic light emitting layer is located between pair of electrodes 5. When the planar light emitting unit is the organic EL element, a thin and transparent light emitter with excellent optical property can be realized. In this case, optical switching device 100 is capable of surface light emission. The organic light emitting layer has optical transparency. Hence, during light emission, light from the organic light emitting layer can be emitted to both sides in the thickness direction. During non-light emission, light can be to transmitted from one side to the other side.

The organic light emitting layer is a layer having a function of emitting light, and may be composed of a plurality of functional layers selected as appropriate from a hole injection layer, a hole transport layer, a light emitting material-containing layer, an electron transport layer, an electron injection layer, an intermediate layer, and the like. The organic light emitting layer may be a single layer of the light emitting material-containing layer. In the organic EL element, holes and electrons are combined in the light emitting material-containing layer to emit light by causing the flow of electricity between pair of electrodes 5.

The current direction in the organic EL element is typically one way. Accordingly, a DC power source may be connected. DC may be converted from AC. The use of a DC power source enables stable light emission. The light emitting color of the organic EL element may be white, and may be blue, green, or red. The light emitting color may be an intermediate color between blue and green or between green and red. Toning may be performed according to applied current.

Plurality of optically variable units 1 may include the light scattering variable unit. The light scattering variable unit is variable in the degree of light scattering. The variability in the degree of light scattering may be the capability of adjusting between a high scattering state and a low scattering state. Alternatively, the variability in the degree of light scattering may be the capability of adjusting between a state with light scattering and a state without light scattering. When the degree of light scattering is adjustable, the optical state can be changed. Such optical switching device 100 has excellent optical property. The light scattering variable unit may be layered.

The high scattering state is a state with high light scattering. The high scattering state is, for example, a state where light which has entered from one surface has its traveling direction changed to various directions by scattering and dispersedly exits from the other surface. The high scattering state may be a state where, when viewing an object present on the other surface side from one surface side, the object appears blurred. The high scattering state may be a translucent state. In the case where the light scattering variable unit performs light scattering, the light scattering variable unit functions as a scattering layer that scatters light.

The low scattering state is a state with low light scattering or no light scattering. The low scattering state is, for example, a state where light which has entered from one surface exits from the other surface while maintaining its traveling direction. The low scattering state may be a state where, when viewing an object present on the other surface side from one surface side, the object is clearly visible. The low scattering state may be a transparent state.

The light scattering variable unit may have the high scattering state with high light scattering, the low scattering state with low light scattering or no light scattering, and a state of performing light scattering between the high scattering state and the low scattering state. When the light scattering variable unit can perform light scattering between the high scattering state and the low scattering state, intermediate light scattering is realized. This enables the optical state to be changed with wide variation, and further improves the optical property. The state of performing light scattering between the high scattering state and the low scattering state is hereafter referred to as an intermediate scattering state.

The intermediate scattering state may have at least one scattering state between the high scattering state and the low scattering state. For example, the optical property is improved if light scattering can be changed by switching between the three states of the high scattering state, the intermediate scattering state, and the low scattering state. The intermediate scattering state may have a plurality of states that differ in the degree of scattering, between the high scattering state and the low scattering state. By setting a plurality of levels in the degree of scattering in this way, the optical property can be further enhanced. For example, the optical property is improved if light scattering can be changed in a plurality of levels by switching between the plurality of states of the high scattering state, the plurality of intermediate scattering states, and the low scattering state. The intermediate scattering state may be a state that changes continuously from the high scattering state to the low scattering state. In such a case, the degree of scattering changes continuously. This enables the optical state to be changed with wide variation, and further improves the optical property. For example, the optical property is improved if light scattering can be changed in a state of performing desired light scattering between the high scattering state and the low scattering state to thus create an intermediate state. In the case where the light scattering variable unit has the intermediate scattering state, the light scattering variable unit may be capable of maintaining the intermediate scattering state.

The intermediate scattering state may have light scattering distribution in the plane. In this case, a part with high light scattering and a part with low light scattering can form a pattern.

The light scattering variable unit may scatter at least part of visible light. The light scattering variable unit may scatter the whole visible light. The light scattering variable unit may scatter infrared light or ultraviolet light.

In the case where optically variable unit 1 is the light scattering variable unit, optically variable layer 2 may be a light scattering variable layer. The light scattering variable layer is located between pair of electrodes 5. The degree of light scattering in the light scattering variable layer is changed by applying a voltage between pair of electrodes 5.

The light scattering variable unit may be connected to an AC power source. Many materials that vary in light scattering according to an electric field are, once time has passed from the start of voltage application, unable to maintain the light scattering state at the time of voltage application. With the AC power source, voltage can be applied alternately in both directions, and continuous voltage application can be substantially performed by changing the voltage direction. Thus, stable light scattering can be achieved by using the AC power source. The AC waveform may be rectangular. This eases the application of constant voltage, and so contributes to more stable light scattering. AC power may be pulses. The intermediate scattering state may be created by controlling the amount of voltage application.

The material of the light scattering variable layer may be a material whose molecular orientation varies according to electric field modulation. For example, the material is a liquid crystal material. The material of the light scattering variable layer may be a polymer dispersed liquid crystal (PDLC). In the PDLC, a liquid crystal is held by a polymer, so that a stable light scattering variable layer can be formed. As the material of the light scattering variable layer, a solid substance that varies in scattering according to an electric field may also be used.

The PDLC may be composed of a resin portion and a liquid crystal portion. The resin portion is formed by a polymer. The resin portion may have optical transparency. This enables the light scattering variable unit to have optical transparency. The resin portion may be made of a thermosetting resin, an ultraviolet curable resin, or the like. The liquid crystal portion is a portion whose liquid crystal structure varies according to an electric field. For example, the liquid crystal portion is a nematic liquid crystal. The PDLC may have a structure in which the liquid crystal portions are scattered in the resin portion. Such PDLC may have a sea-island structure where the resin portion is the sea and the liquid crystal portions are the islands. The PDLC may have a shape in which the liquid crystal portions arc irregularly connected like a net in the resin portion. Alternatively, the PDLC may have a structure in which the resin portions are scattered in the liquid crystal portion or the resin portions are irregularly connected like a net in the liquid crystal portion.

The light scattering variable unit may be in the light scattering state when no voltage is applied, and in the light transmission state when a voltage is applied. Such control may be performed with the PDLC. This is because a liquid crystal can be aligned by voltage application. With the PDLC, a thin light scattering variable unit with high light scattering property can be formed. The light scattering variable unit may be in the light transmission state when no voltage is applied, and in the light scattering state when a voltage is applied.

The light scattering variable layer may maintain the light scattering state at the time of voltage application. This enhances power efficiency. The property of maintaining the light scattering state is called hysteresis. The time for maintaining the light scattering state may be long, e.g. one hour or more.

Plurality of optically variable units 1 may include the light reflection variable unit. The light reflection variable unit is variable in the degree of light reflection. The variability in the degree of light reflection may be the capability of adjusting between a high reflection state and a low reflection state. Alternatively, the variability in the degree of light reflection may be the capability of adjusting between a state with light reflection and a state without light reflection. When the degree of light reflection is adjustable, the optical state can be changed. Such optical switching device 100 has excellent optical property. The light reflection variable unit may be layered.

The high reflection state is a state with high light reflection. The high reflection state is, for example, a state where light which has entered from one surface has its traveling direction changed to the opposite direction by reflection and exits from the surface of incidence. The high reflection state may be a state where an object present on the other surface side is not visible from one surface side. The high reflection state may be a state where, when viewing the light reflection variable unit from one surface side, an object present on the same surface side is visible. The high reflection state may be a mirror state. In the case where the light reflection variable unit performs light reflection, the light reflection variable unit functions as a reflection layer that reflects light.

The low reflection state is a state with low light reflection or no light reflection. The low reflection state is, for example, a state where light which has entered from one surface exits from the other surface while maintaining its traveling direction. The low reflection state may be a state where, when viewing an object present on the other surface side from one surface side, the object is clearly visible. The low reflection state may be a transparent state.

The light reflection variable unit may have the high reflection state with high light reflection, the low reflection state with low light reflection or no light reflection, and a state of performing light reflection between the high reflection state and the low reflection state. When the light reflection variable unit can perform light reflection between the high reflection state and the low reflection state, intermediate light reflection is realized. This enables the optical state to be changed with wide variation, and further improves the optical property. The state of performing light reflection between the high reflection state and the low reflection state is hereafter referred to as an intermediate reflection state.

The intermediate reflection state may have at least one reflection state between the high reflection state and the low reflection state. For example, the optical property is improved if light reflection can be changed by switching between the three states of the high reflection state, the intermediate reflection state, and the low reflection state. The intermediate reflection state may have a plurality of states that differ in the degree of reflection, between the high reflection state and the low reflection state. By setting a plurality of levels in the degree of reflection in this way, the optical property can be further enhanced. For example, the optical property is improved if light reflection can be changed in a plurality of levels by switching between the plurality of states of the high reflection state, the plurality of intermediate reflection states, and the low reflection state. The intermediate reflection state may be a state that changes continuously from the high reflection state to the low reflection state. In such a case, the degree of reflection changes continuously. This enables the optical state to be changed with wide variation, and further improves the optical property. For example, the optical property is improved if light reflection can be changed in a state of performing desired light reflection between the high reflection state and the low reflection state to thus create an intermediate state. In the case where the light reflection variable unit has the intermediate reflection state, the light reflection variable unit may be capable of maintaining the intermediate reflection state.

The intermediate reflection state may have light reflection distribution in the plane. In this case, a part with high light reflection and a past with low light reflection can form a pattern.

The light reflection variable unit may reflect at least part of visible light. The light reflection variable unit may reflect the whole visible light. The light reflection variable unit may reflect infrared light. The light reflection variable unit may reflect ultraviolet light. In the case where the light reflection variable unit reflects all of visible light, ultraviolet light, and infrared light, the optical switching device 100 is stable and has excellent optical property.

The light reflection variable unit may be capable of changing the shape of reflection spectrum. The reflection spectrum may be changed in the intermediate reflection state. Changing the shape of reflection spectrum means that light entering the light reflection variable unit and light reflected in the light reflection variable unit have different spectrum shapes. The reflection spectrum is changed by changing the reflection wavelength. For example, the shape of reflection spectrum is changed by strongly reflecting only blue light, strongly reflecting only green light, or strongly reflecting only red light. When the reflection spectrum changes, the color of light changes. This enables toning (color adjustment), and improves the optical property.

The light reflection variable unit may be capable of reflecting light without changing the shape of reflection spectrum. In such a case, since there is no spectrum change between incident light and reflected light, the degree of reflection can be easily increased or decreased. The capability of controlling the degree of reflection enables dimming (brightness adjustment), and improves the optical property.

In the case where optically variable unit 1 is the light reflection variable unit, optically variable layer 2 may be a light reflection variable layer. The light reflection variable layer is located between pair of electrodes 5. The degree of light reflection in the light reflection variable layer is changed by applying a voltage between pair of electrodes 5.

The light reflection variable unit may be connected to an AC power source. Many materials that vary in light reflection according to an electric field are, once time has passed from the start of voltage application, unable to maintain the light reflection state at the time of voltage application. With the AC power source, voltage can be applied alternately in both directions, and continuous voltage application can be substantially performed by changing the voltage direction. Thus, stable light reflection can be achieved by using the AC power source. The AC waveform may be rectangular. This eases the application of constant voltage, and so contributes to more stable light reflection. AC power may be pulses. The intermediate reflection state may be created by controlling the amount of voltage application.

The material of the light reflection variable layer may be a material whose molecular orientation varies according to electric field modulation. Examples include a nematic liquid crystal, a cholesteric liquid crystal (CLC), a ferroelectric liquid crystal, and an electrochromic material. The CLC may be a nematic liquid crystal having a helical structure. The CLC may be a chiral nematic liquid crystal. In the CLC, the orientation direction of the molecular axis changes continuously in the space, creating a macroscopic helical structure. Light reflection corresponding to the helical period is therefore possible. Control between light reflection and light transmission can be performed by changing the liquid crystal state according to an electric field. In the electrochromic material, the color change phenomenon of the substance by electrochemical reversible reaction (electrolytic oxidation-reduction reaction) according to voltage application can be utilized to enable control between light reflection and light transmission. The material of the light reflection variable layer may be the CLC or the electrochromic material.

The light reflection variable unit may be in the light reflection state when no voltage is applied, and in the light transmission state when a voltage is applied. Such control may be performed with the CLC or the electrochromic material. This is because a liquid crystal can be aligned by voltage application. With the CLC or the electrochromic material, a thin light reflection variable unit with high light reflection property can be formed. The state of reflecting only specific light without voltage application may be referred to as planar orientation, and the state of allowing light to pass with voltage application as focal-conic orientation. The light reflection variable unit may be in the light transmission state when no voltage s applied, and in the light reflection state when a voltage is applied.

The light reflection variable layer may maintain the light reflection state at the time of voltage application. This enhances power efficiency. The property of maintaining the light reflection state is called hysteresis. The time for maintaining the light reflection state may be long, e.g. one hour or more.

Plurality of optically variable units 1 may include the light absorption variable unit. The light absorption variable unit is variable in the degree of light absorption. The variability in the degree of light absorption may be the capability of adjusting between a high absorption state and a low absorption state. Alternatively, the variability in the degree of light absorption may be the capability of adjusting between a state with light absorption and a state without light absorption. When the degree of light absorption is adjustable, the optical state can be changed. Such optical switching device 100 has excellent optical property. The light absorption variable unit may be layered.

The high absorption state is a state with high light absorption. The high absorption state is, for example, a state where light which has entered from one surface does not exit from the other surface by absorption. The high absorption state may be a state where an object present on the other surface side is not visible from one surface side. The high absorption state may be a state where an object present on the other surface side is not visible from each surface side. The high absorption state may be an opaque state. In the high absorption state, the light absorption variable unit may be black in color. In the case where the light absorption variable unit performs light absorption, the light absorption variable unit functions as an absorption layer that absorbs light.

The low absorption state is a state with low light absorption or no light absorption. The low absorption state is, for example, a state where light which has entered from one surface is not absorbed and exits from the other surface while maintaining its traveling direction. The low absorption state may be a state where, when viewing an object present on the other surface side from one surface side, the object is clearly visible. The low absorption state may be a transparent state.

The light absorption variable unit may have the high absorption state with high light absorption, the low absorption state with low light absorption or no light absorption, and a state of performing light absorption between the high absorption state and the low absorption state. When the light absorption variable unit can perform light absorption between the high absorption state and the low absorption state, intermediate light absorption is realized. This enables the optical state to be changed with wide variation, and further improves the optical property. The state of performing light absorption between the high absorption state and the low absorption state is hereafter referred to as an intermediate absorption state.

The intermediate absorption state may have at least one absorption state between the high absorption state and the low absorption state. For example, the optical property is improved if light absorption can be changed by switching between the three states of the high absorption state, the intermediate absorption state, and the low absorption state. The intermediate absorption state may have a plurality of states that differ in the degree of absorption, between the high absorption state and the low absorption state. By setting a plurality of levels in the degree of absorption in this way, the optical property can be further enhanced. For example, the optical property is improved if light absorption can be changed in a plurality of levels by switching between the plurality of states of the high absorption state. The plurality of intermediate absorption states, and the low absorption state. The intermediate absorption state may be a state that changes continuously from the high absorption state to the low absorption state. In such a case, the degree of absorption changes continuously. This enables the optical state to be changed with wide variation, and further improves the optical property. For example, the optical property is improved if light absorption can be changed in a state of performing desired light absorption between the high absorption state and the low absorption state to thus create an intermediate state. In the case where the light absorption variable unit has the intermediate absorption state, the light absorption variable unit may be capable of maintaining the intermediate absorption state.

The intermediate absorption state may have light absorption distribution in the plane. In this case, a part with high light absorption and a part with low light absorption can form a pattern.

The light absorption variable unit may absorb at least part of visible light. This produces sharp light emission. The light absorption variable unit may absorb the whole visible light. This produces sharper light emission. The light absorption variable unit may absorb infrared light. Absorbing infrared light has a heat shielding effect. The light absorption variable unit may absorb ultraviolet light. This prevents the degradation of optical switching device 100. Moreover, by absorbing ultraviolet light, ultraviolet light can be kept from entering indoors. The light absorption variable unit may absorb any one of visible light, ultraviolet light, and infrared light, may absorb any two of visible light, ultraviolet light, and infrared light, and may absorb all of visible light, ultraviolet light, and infrared light.

The light absorption variable unit may be capable of changing shape of absorption spectrum. The absorption spectrum may be changed in the intermediate absorption state. Changing the shape of absorption spectrum means that light entering the light absorption variable unit and light having passed through the light absorption variable unit have different spectrum shapes. The absorption spectrum is changed by changing the absorption wavelength. For example, the spectrum shape is changed by strongly absorbing only blue light, strongly absorbing only green light, or strongly absorbing only red light. When the absorption spectrum changes, the color of light passing through optical switching device 100 changes. This enables toning (color adjustment) for transmitted light, and improves the optical property.

In the case where optically variable unit 1 is the light absorption variable unit, optically variable layer 2 may be a light absorption variable layer. The light absorption variable layer is located between pair of electrodes 5. The degree of light absorption in the light absorption variable layer is changed by applying a voltage between pair of electrodes 5.

The light absorption variable unit may be connected to a DC power source or an AC power source. For example, the light absorption variable unit is connected to a DC power source. In a material whose light absorption varies according to an electric field, light absorption can be changed by the flow of electricity in one direction. Thus, stable light absorption can be achieved by using the DC power source. The intermediate absorption state may be created by controlling the amount of voltage or current application.

The material of the light absorption variable layer may be a material whose light absorption varies according to electric field modulation. The material for electric field modulation is, for example, tungsten oxide.

The light absorption variable unit may be in the light transmission state when no voltage is applied, and in the light absorption state when a voltage is applied. A liquid crystal material can change in absorption according to voltage application. A liquid crystal can be aligned according to voltage application. With the liquid crystal, a thin light absorption variable unit with high absorption property can be formed. The light absorption variable unit may be in the light absorption state when no voltage is applied, and in the light transmission state when a voltage is applied.

The light absorption variable layer may maintain the light, absorption state at the time of voltage application. This enhances power efficiency. The property of maintaining the light absorption state is called hysteresis. The time for maintaining the light absorption state may be long, e.g. one hour or more.

In optical switching device 100, first surface F1 is defined as a main surface, and second surface F2 as a back surface. The main surface is set in the direction in which light is to be obtained. For example, in the case where optical switching device 100 is used as a window, the main surface (first surface F1) is situated inside and the back surface (second surface F2) is situated outside.

Table 1 shows examples of the structure of plurality of optically variable units 1. In Table 1, each component which optical switching device 100 has as optically variable unit 1 is indicated by “∘”. Table 1 also shows the functions in the case of selecting each component. Optically variable units 1 may be arranged in any order.

TABLE 1

| | Light | | Light | Light | |
|---|---|---|---|---|---|
| Struc- | scat- | Planar | reflec- | absorp- | |
| tural | tering | light | tion | tion | |
| exam- | variable | emitting | variable | variable | |
| ple | unit | unit | unit | unit | Function |
| 1 | ∘ | ∘ | | | Suppression of angular |
| | | | | | dependence of light |
| | | | | | emission |
| 2 | | ∘ | ∘ | | Improvement of light |
| | | | | | emission efficiency |
| 3 | | | ∘ | ∘ | Light shielding |
| | | | | | Usable as mirror |
| 4 | ∘ | | | ∘ | Light shielding |
| | | | | | White lightproof |
| | | | | | curtain |
| | | | | | Lace curtain |
| 5 | | ∘ | | ∘ | Improvement of contrast |
| | | | | | of light emission |
| 6 | ∘ | | ∘ | | Light shielding |
| | | | | | Improvement of thermal |
| | | | | | insulation |
| 7 | ∘ | ∘ | ∘ | | High-efficiency light |
| | | | | | emission |
| | | | | | Suppression of angular |
| | | | | | dependence of light |
| | | | | | emission |
| 8 | | ∘ | ∘ | ∘ | Light shielding |
| | | | | | High-efficiency light |
| | | | | | emission |
| | | | | | Improvement of contrast |
| | | | | | of light emission |
| 9 | ∘ | ∘ | | ∘ | Window and lighting |
| | | | | | function |
| 10 | ∘ | | ∘ | ∘ | Window function (light |
| | | | | | shielding, curtain, |
| | | | | | thermal insulation) |
| 11 | ∘ | ∘ | ∘ | ∘ | All of foregoing |
| | | | | | functions |

The light reflection variable unit may be located closer to second surface F2 than the planar light emitting unit and the light scattering variable unit. In this case, light can be extracted using reflection. Such optical switching device 100 has excellent optical property.

The light absorption variable unit may be located closest to second surface F2 of plurality of optically variable units 1. In this case, light entering from second surface F2 can be absorbed. Moreover, light exiting from first surface F1 has higher contrast.

Plurality of optically variable units 1 may be arranged in the order of the light scattering variable unit, the planar light emitting unit, the light reflection variable unit, and the light absorption variable unit in the direction from first surface F1 to second surface F2. In the case where the number of optically variable units 1 is two or three, suitable arrangement is derived by removing part of the aforementioned four units.

In optical switching device 100, plurality of optically variable units 1 may include the organic electroluminescent element (planar light emitting unit) and the light scattering variable unit. A planar light emitter with excellent optical property can thus be obtained. The planar light emitter may be used as a lighting device.

Although the above describes an example where plurality of optically variable units 1 are each a different one of any of the light scattering variable unit, the planar light emitting unit, the light reflection variable unit, and the light absorption variable unit, two or more components of the same type may be selected. For example, plurality of optically variable units 1 may include two or more light scattering variable units. For example, plurality of optically variable units 1 may include two or more planar light emitting units. For example, plurality of optically variable units 1 may include two or more light reflection variable units. For example, plurality of optically variable units 1 may include two or more light absorption variable units. The inclusion of two or more components of the same type of function (scattering, light emission, reflection, or absorption) enhances the function.

FIG. 4 illustrates an example of pair of electrodes 5 in optical switching device 100. In optical switching device 100, each of pair of electrodes 5 in at least one of plurality of optically variable units 1 is connected to plurality of power supply terminals 3. FIG. 4 illustrates pair of electrodes 5 connected to plurality of power supply terminals 3. A in FIG. 4 illustrates one electrode 5 and plurality of power supply terminals 3 connected to electrode 5. B in FIG. 4 illustrates one pair of electrodes 5 and plurality of power supply terminals 3. In B in FIG. 4, one of pair of electrodes 5 is designated as electrode 5x, and the other one of pair of electrodes 5 as electrode 5y. Optically variable unit 1 having pair of electrodes 5 connected to plurality of power supply terminals 3 is defined as a controlled optically variable unit. In optical switching device 100, at least one of plurality of optically variable units 1 is a controlled optically variable unit. In the controlled optically variable unit, at least one of current and voltage in electric power supplied from power supply terminal 3 is controlled in a plurality of levels. Power supply terminal 3 is realized by an appropriate terminal such as an electrode pad and a wiring connection structure.

In the case where the shape of optical switching device 100 is a quadrilateral, plurality of power supply terminals 3 may be located at least at the four corners of the quadrilateral. This increases variation in power supply pattern, and allows the optical state of optical switching device 100 to be changed effectively. Plurality of power supply terminals 3 may further be located at any intermediate point on any side of the quadrilateral.

Pair of electrodes 5 illustrated in FIG. 4 may be applied to at least one of the planar light emitting unit, the light scattering variable unit, the light reflection variable unit, and the light absorption variable unit. In the controlled optically variable unit, the optical state changes in the plane with distribution. The controlled optically variable unit may be variable in optical state in the plane with distribution. At least two of the planar light emitting unit, the light scattering variable unit, the light reflection variable unit, and the light absorption variable unit may each be the controlled optically variable unit. At least three of the planar light emitting unit, the light scattering variable unit, the light reflection variable unit, and the light absorption variable unit may each be the controlled optically variable unit. All of the planar light emitting unit, the light scattering variable unit, the light reflection variable unit, and the light absorption variable unit may each be the controlled optically variable unit.

Plurality of power supply terminals 3 are each capable of independently supplying electric power. At least one of current and voltage in electric power supplied from power supply terminal 3 is controlled in a plurality of levels. The plurality of levels include a high value state, a low value state, and at least one intermediate value state in current or voltage. The plurality of levels may be discontinuous or continuous.

Optically variable unit 1 in optical switching device 100 may be subject to current driving or voltage driving. In current driving, optically variable unit 1 is driven with controlled current. In voltage driving, optically variable unit 1 is driven with controlled voltage. By employing one of current driving and voltage driving, optically variable unit 1 is driven suitably. The planar light emitting unit (organic EL element) may be current driven. The planar light emitting unit may accordingly have current controlled in a plurality of levels. The light scattering variable unit may be voltage driven. The light scattering variable unit may accordingly have voltage controlled in a plurality of levels. The light reflection variable unit may be voltage driven. The light reflection variable unit may accordingly have voltage controlled in a plurality of levels. The light absorption variable unit may be current driven. The light absorption variable unit may accordingly have current controlled in a plurality of levels.

In the controlled optically variable unit, the optical state is variable non-uniformly in the plane as a result of the action of plurality of power supply terminals 3. For example, a part with high optical state and a part with low optical state may appear to form a pattern. In the case where optically variable unit 1 changes optically in a predetermined pattern, the optical state of one point in the plane and the optical state of another point in the plane sufficiently away from the point may change to different states. For example, in the case where the region that changes optically is a quadrilateral, optically variable unit 1 may change optically so that the optical state differs between diagonally opposite corners.

FIG. 5 is a graph and view illustrating the change of the optical state of optically variable unit 1 (controlled optically variable unit). FIG. 5 illustrates an example where optically variable unit 1 is the light scattering variable unit or the light, reflection variable unit. As illustrated in FIG. 5, the optical state of optically variable unit 1 is changed from opaque to transparent by voltage control. FIG. 5 illustrates an example of the change of the optical state of optically variable unit 1, and the change of the optical state is not limited to this. The term “opaque” used with reference to FIG. 5 denotes a state with low transparency, e.g. a state where an object on the other side of optically variable unit 1 is not visible or not clearly visible. The term “transparent” used with reference to FIG. 5 denotes a state with higher transparency than opaque, e.g. a state where an object on the other side of optically variable unit 1 is clearly visible. In this example, optically variable unit 1 is opaque when no voltage is applied, and transparent when a voltage of a predetermined value or more is applied.

FIG. 5 corresponds to the case where voltage is applied from power supply terminal 3 at the upper right corner from among plurality of power supply terminals 3 in FIG. 4. Plurality of power supply terminals 3 are each capable of independently supplying electric power. Hence, electric power can be supplied, for example, from only upper right power supply terminal 3. Power supply terminal 3 is capable of multilevel control, and can apply voltage in multiple levels (a plurality of different voltage values).

The changes in optical transparency at three points, i.e. point P1 at the upper right corner, point P2 at the center, and point P3 at the lower left corner, in the planar region where the optical state changes when voltage is applied from the upper right corner are compared as illustrated in B in FIG. 5. The graph in A in FIG. 3 illustrates the relationship between the voltage and the light transmittance in each of points P1, P2, and P3.

As can be seen from A in FIG. 5, at voltage 0 (V) where no voltage is applied, light transmittance is low in all of points P1 to P3, and optically variable unit 1 is opaque. Voltage E1 (V) is then applied from the upper right. At voltage E1 (V), light transmittance increases in upper right point P1 near the voltage application position, and point P1 changes from opaque to transparent. Moreover, at voltage E1 (V), light transmittance increases in center point P2 but transparency is not as high as upper right point P1, and point P2 has a degree of transparency between opaque and transparent. Further, at voltage E1 (V), light transmittance does not increase or increases only slightly in lower left point P3, and point P3 remains opaque. Thus, transparency changes in the plane with distribution. This state may be maintained during the application of voltage E1 (V). Voltage E2 (V) higher than voltage E1 (V) is then applied. For example, E1 is 100 (V), and E2 is 150 (V). At voltage E2 (V), light transmittance increases in center point P2 and lower left point P3 as well, and center point P2 and lower left point P3 change from opaque to transparent. As a result, optically variable unit 1 is transparent in the whole plane. By such voltage control, transparency changes in the plane in pattern. If voltage is gradually increased from 0 (V) to E2 (V) stepwise or continuously various transparency patterns are formed as transparency gradually spreads from the upper right and eventually reaches the lower left, as can be understood from the graph in A in FIG. 5. Moreover, by changing the voltage application position, various patterns can be formed from transparent and opaque parts.

Although FIG. 5 illustrates an example of voltage control, current control may be performed in the same manner. Although the above describes the case where the optical state is changed to transparent when supplied with electric power, the same control may also be performed in the case where the optical state is changed from transparent to opaque when supplied with electric power in optically variable unit 1. With the flow of electricity, the planar light emitting unit (organic EL element) may generate light and change its light emitting state from transparent to opaque. With the application of voltage, the light scattering variable unit may decrease in scattering and change from opaque to transparent. With the application of voltage, the light reflection variable unit may decrease in reflection and change from opaque to transparent. With the flow of electricity, the light absorption variable unit may increase in absorption and change from transparent to opaque. Each of the aforementioned units also has the intermediate state for its function (for example, the intermediate scattering state in the case of scattering), and may change from the high functioning state to the intermediate functioning state and vice versa, or change from the intermediate functioning state to the low functioning state and vice versa. Thus, control may be performed so that the optical state changes in the plane in pattern. Such a change that forms a pattern with opaque and/or transparent parts is hereafter referred to as a pattern change.

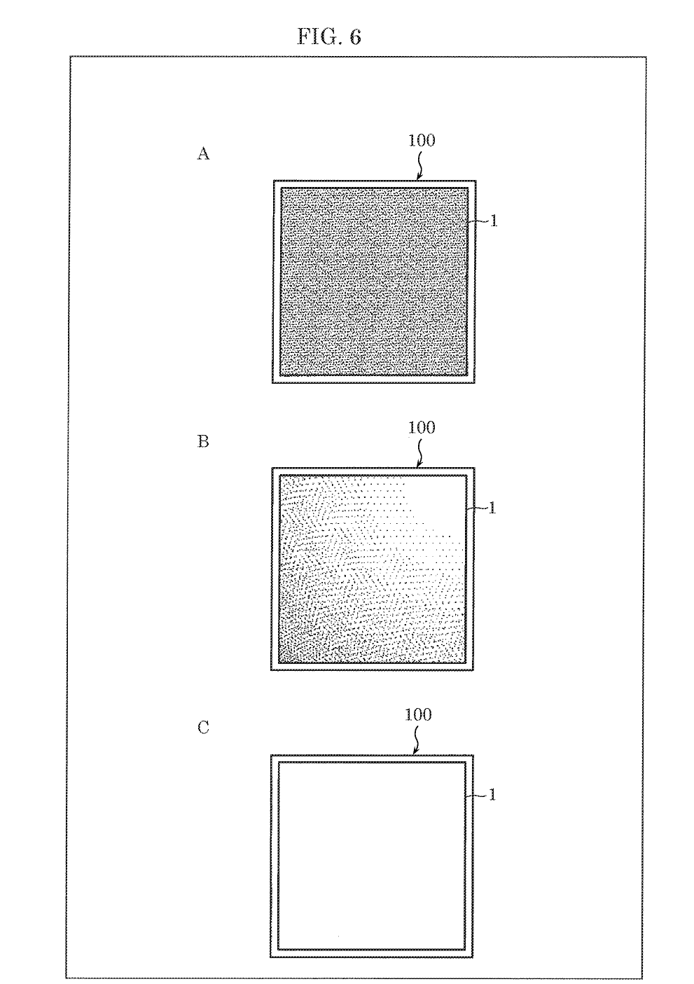

FIG. 6 illustrates an example of the change of the optical state of optical switching device 100. The pattern change control illustrated in FIG. 5 is used in FIG. 6.

As illustrated in FIG. 6, optical switching device 100 may produce an optical pattern of gradually changing from opaque to transparent from the upper right toward the lower left, by the action of optically variable unit 1. In FIG. 6, the level of transparency is expressed by the density of dots, with higher transparency corresponding to lower dot density. A in FIG. 6 corresponds to 0 (V) in A in FIG. 5, where optical switching device 100 is entirely opaque. B in FIG. 6 corresponds to E1 (V) in A in FIG. 5, where optical switching device 100 is transparent in the upper right, gradually decreases in transparency toward the lower left, and is opaque in the lower left. The state in B in FIG. 6 has a pattern in transparency, and can be defined as a pattern forming state. C in FIG. 6 corresponds to E2 (V) in A in FIG. 5, where optical switching device 100 is entirely transparent. As described above, optical switching device 100 may have a pattern of transparency changing in the plane.

A pattern change in optical state between transparent and opaque may be performed in at least one of plurality of optically variable units 1 (planar light emitting unit, light scattering variable unit, light reflection variable unit, and light absorption variable unit). A pattern change may be performed in all of plurality of optically variable units 1. Of plurality of optically variable units 1, optically variable unit 1 having pair of electrodes 5 connected to plurality of power supply terminals 3 has a pattern change. In the case where a pattern change is performed in plurality of optically variable units 1, plurality of optically variable units 1 may have the same pattern change. This makes the pattern change more effective.

The aforementioned optical change control uses in-plane electric resistance in electrode 5. Planar electrode 5 has higher electric resistance, and allows less electricity to pass through. In particular, electrode 5 having optical transparency tends to have high electric resistance. This eases changing the optical state between a point near power supply terminal 3 and a point far from power supply terminal 3. The planar electric resistance may be sheet resistance. The sheet resistance may be 10Ω or more, and may be 20Ω or more. Higher electric resistance facilitates pattern change control. Excessively high electric resistance, however, causes an increase in drive voltage and leads to higher power consumption.

As illustrated in FIG. 4, one electrode 5 of pair of electrodes 5 is connected to plurality of power supply terminals 3, and the other electrode 5 is also connected to plurality of power supply terminals 3. Hence, a voltage difference or a current difference is more easily created in the plane using the voltage or current distribution in one electrode 5 and the voltage or current distribution in the other electrode 5, with it being possible to achieve effective optical pattern change. For example, by setting the voltage of one electrode 5 at one part to +10 V and the voltage of the other electrode 5 at the corresponding part (the overlapping position in planar view) to −10 V, a voltage difference of 20 V in total can be generated, thus enhancing efficiency. Moreover, by controlling the position or strength of power supply from power supply terminal 3, a large amount of electricity can be caused to flow through a certain part in the plane.

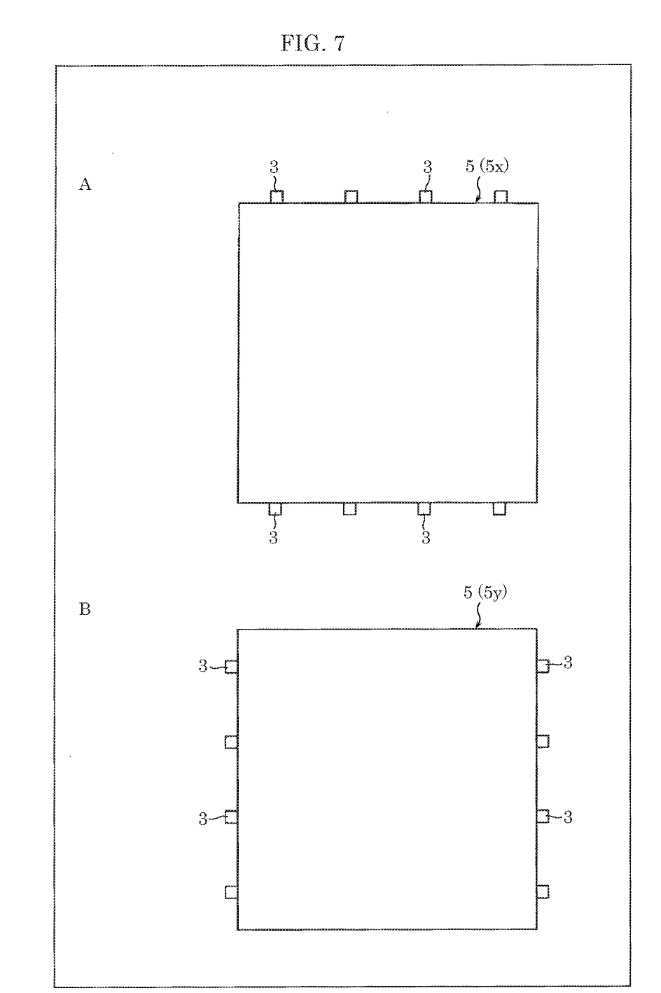

FIG. 7 illustrates an example of pair of electrodes 5. A in FIG. 7 illustrates one (5x) of pair of electrodes 5, and B in FIG. 7 illustrates the other one (5y) of pair of electrodes 5. Electrode 5 is illustrated in planar view in A and B in FIG. 7. Electrodes 5x and 5y illustrated in A and B in FIG. 7 can be stacked in the direction perpendicular to the plane of paper. The arrangement of pair of electrodes 5 can be understood from B in FIG. 4. Pair of electrodes 5 illustrated in FIG. 7 are applied to optically variable unit 1.

The example in FIG. 7 differs from the example in FIG. 4 in the b connection pattern of plurality of power supply terminals 3. In the example in FIG. 4, pair of electrodes 5 are connected to power supply terminals 3 in the same pattern. In FIG. 4, four power supply terminals 3 are arranged at regular intervals on each of the four sides of quadrilateral electrode 5. In the example in FIG. 7, on the other hand, plurality of power supply terminals 3 are arranged on each of two opposite sides of the quadrilateral, while no power supply terminals 3 are arranged on the other two sides. Power supply terminals 3 are present on the upper and lower two sides in A in FIG. 7, and power supply terminals 3 are present on the right and left two sides in B in FIG. 7. In other words, the connection positions of power supply terminals 3 differ between pair of electrodes 5. Pair of electrodes 5 may thus be connected to plurality of power supply terminals 3 in different patterns. The number of power supply terminals 3 can be reduced in such a case, which contributes to a simpler structure. Moreover, in the case where the connection pattern of power supply terminals 3 differs depending on electrode 5, electric power can be supplied using fewer power supply terminals 3. Hence, electric power can be supplied efficiently in the plane. The optical pattern formation can be performed efficiently, too.

In the case where the shape of optical switching device 100 is a quadrilateral, power supply terminals 3 may be provided so that the sides having power supply terminals 3 do not overlap between pair of electrodes 5, as illustrated in FIG. 7. This enhances efficiency. In addition, an optical pattern made up of a part with high optical state and a part with low optical state can be formed effectively.

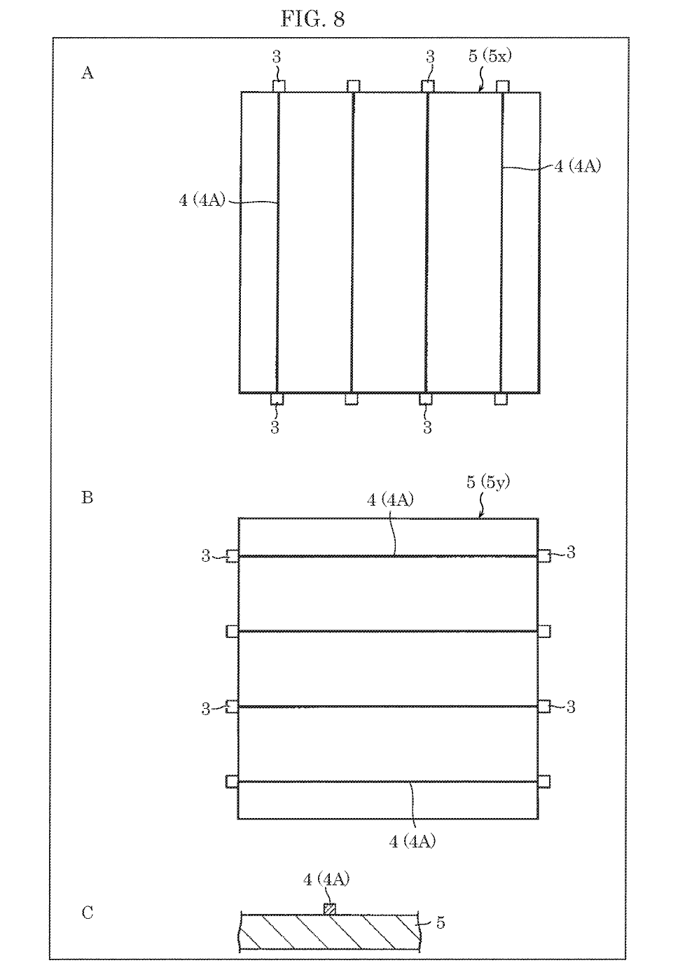

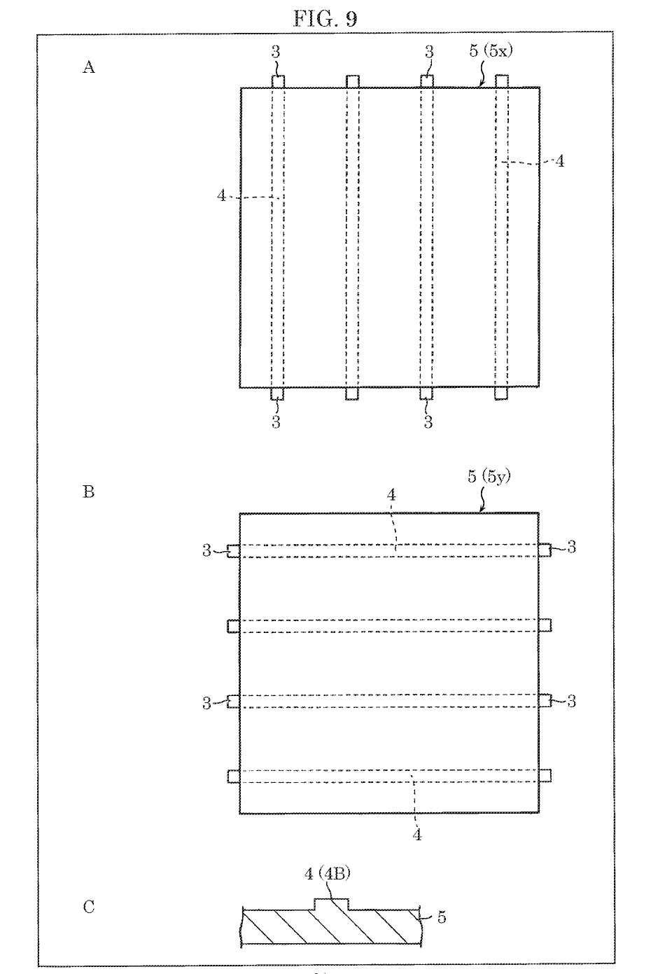

FIGS. 8 and 9 each illustrate an example of electrodes 5 provided with low resistance portion 4. Optical switching device 100 may include low resistance portion 4 extending in the plane of optically variable unit 1. Low resistance portion 4 may be in contact with electrode 5. Low resistance portion 4 may be provided on each of pair of electrodes 5. Low resistance portion 4 is a portion lower in electric resistance than electrode 5. Low resistance portion 4 aids in-plane conduction in electrode 5, allowing more electric power to be supplied to the inside. Hence, a state where transparent and opaque parts are mixed in the plane to form a pattern can be created more effectively. The presence of low resistance portion 4 helps producing a balance between the optical state of the edges and the optical state of the center, and facilitates the creation of a beautiful pattern even in a large area.

Low resistance portion 4 may electrically connect plurality of power supply terminals 3 in the plane. This further stabilizes electric power supply. Low resistance portion 4 may be linear. Linear low resistance portion 4 eases changing the optical state in pattern.

FIG. 8 illustrates an example of pair of electrodes 5. A in FIG. 8 illustrates one (5x) of pair of electrodes 5, and B in FIG. 8 illustrates the other one (5y) of pair of electrodes 5. Electrode 5 is illustrated in planar view in A and B in FIG. 8. Electrodes 5x and 5y illustrated in A and B in FIG. 8 can be stacked in the direction perpendicular to the plane of paper. The arrangement of pair of electrodes 5 can be understood from B in FIG. 4. Pair of electrodes 5 illustrated in FIG. 8 are applied to optically variable unit 1. C in FIG. 8 is a sectional view of electrode 5 at the position where low resistance portion 4 is provided.

In the example of electrode 5x illustrated in A in FIG. 8, power supply terminals 3 are arranged on the upper and lower two opposite sides, and low resistance portion 4 is provided to connect each pair of upper and lower power supply terminals 3. In the example of electrode 5y illustrated in B in FIG. 8, power supply terminals 3 are arranged on the right and left two opposite sides, and low resistance portion 4 is provided to connect each pair of right and left power supply terminals 3. Low resistance portion 4 may be in contact with each power supply terminal 3.

In the example in FIG. 8, low resistance portion 4 is auxiliary wiring 4A. Auxiliary wiring 4A is located on the surface of electrode 5, as illustrated in C in FIG. 8. Forming low resistance portion 4 using auxiliary wiring 4A improves conductivity. As a result, electricity can be efficiently conveyed to the inside. For example, auxiliary wiring 4A is made of metal. Examples of the metal include silver and aluminum. The width of auxiliary wiring 4A may be in the range of 1 μm to 500 μm. Auxiliary wiring 4A may be linear. Auxiliary wiring 4A may be opaque. Auxiliary wiring 4A is narrow, and so hardly decreases the optical state of optical switching device 100. Thus, auxiliary wiring 4A can enhance electric conductivity while maintaining the optical state. Auxiliary wiring 4A may be tapered. Tapered auxiliary wiring 4A improves electric reliability.

FIG. 9 illustrates an example of pair of electrodes 5. A in FIG. 9 illustrates one (5x) of pair of electrodes 5, and B in FIG. 9 illustrates the other one (5y) of pair of electrodes 5. Electrode 5 is illustrated in planar view in A and B in FIG. 9. Electrodes 5x and 5y illustrated in A and B in FIG. 9 can be stacked in the direction perpendicular to the plane of paper. The arrangement of pair of electrodes 5 can be understood from B in FIG. 4. Pair of electrodes 5 illustrated in FIG. 9 are applied to optically variable unit 1. C in FIG. 9 is a sectional view of electrode 5 at the position where low resistance portion 4 is provided.

In FIG. 9, low resistance portion 4 is in contact with electrode 5, as in FIG. 8. Low resistance portion 4 connects power supply terminals 3 located on the two opposite sides.

In the example in FIG. 9, low resistance portion 4 is transparent conductive portion 4B. Transparent conductive portion 4B is made of a conductive material having transparency. Transparent conductive portion 4B may be a portion of electrode 5 increased in thickness. Such transparent conductive portion 4B can be formed easily. In C in FIG. 9, electrode 5 is increased in thickness to form transparent conductive portion 4B. Transparent conductive portion 4B may be a protrusion of electrode 5. The thicker portion of electrode 5 is lower in electric resistance, and has improved conductivity as compared with the other portions. Since electrode 5 is transparent, transparency is maintained even when electrode 5 is increased in thickness. Thus, transparent conductive portion 4B can enhance electric conductivity while maintaining transparency. The width of transparent conductive portion 4B is not particularly limited, and may be in the range of 10 μm to 10000 μm. Transparent conductive portion 4B may be tapered. Tapered transparent conductive portion 4B improves electric reliability.

Although FIGS. 8 and 9 illustrate an example where linear low resistance portion 4 connects power supply terminals 3 on two opposite sides of the quadrilateral, the pattern of connection by low resistance portion 4 is not limited to this. For example, in the case where plurality of power supply terminals 3 are arranged on two adjacent sides of the quadrilateral, low resistance portion 4 may connect power supply terminals 3 on the two adjacent sides. Although the above describes an example where low resistance portion 4 connects two power supply terminals 3, low resistance portion 4 may connect three or more power supply terminals 3. Low resistance portion 4 and power supply terminals 3 may be connected in any arrangement that facilitates the obtainment of an optical pattern.

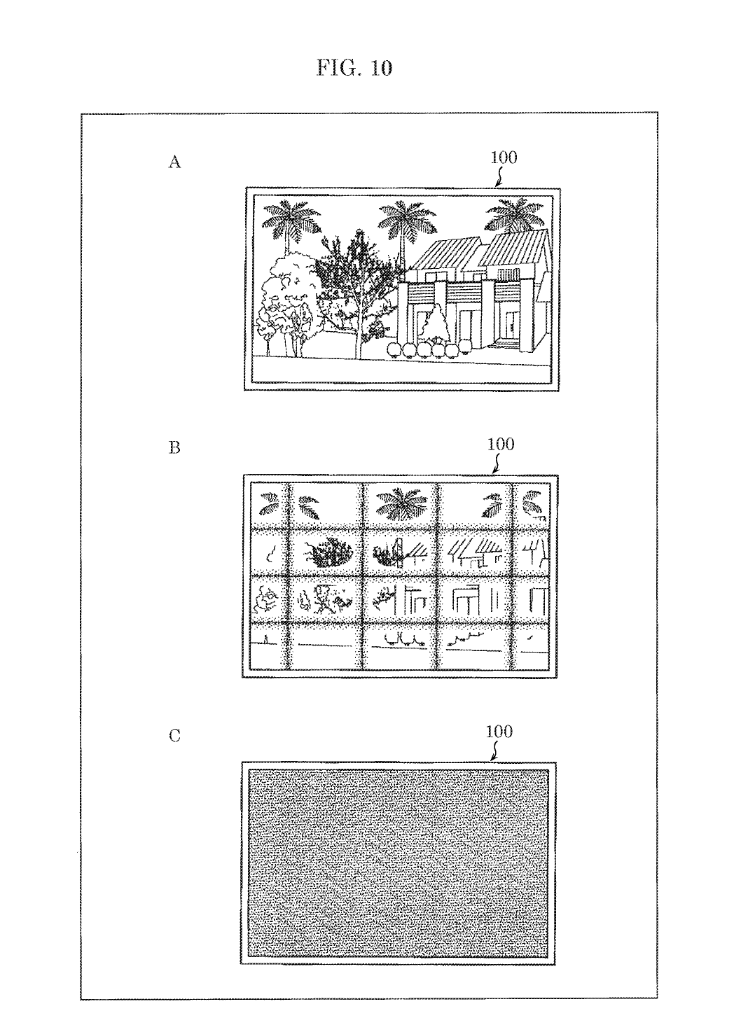

FIG. 10 illustrates an example of how the optical state of optical switching device 100 changes in pattern. FIG. 10 illustrates control for forming a pattern of a grid opaque region. The scenery seen on the other side of optical switching device 100 is schematically illustrated to help understanding the optical state change. In A in FIG. 10, optical switching device 100 is transparent, and so the scenery is visible. In B in FIG. 10, optical switching device 100 has opaque parts in grid form and transparent parts between the opaque parts in grid form, and so the scenery is partially visible through the grid. The opaque parts are in a grid pattern. In C in FIG. 10, optical switching device 100 is opaque, and so the scenery is not visible. Optical switching device 100 can form a pattern with transparent and opaque parts as illustrated in B in FIG. 10.

As illustrated in FIG. 10, various pattern changes are possible by controlling the power supply from plurality of power supply terminals 3 to pair of electrodes 5. The grid pattern can be easily formed, for example, using pair of electrodes 5 illustrated in FIG. 8 or 9. In pair of electrodes 5 in FIG. 8 or 9, the extending direction of low resistance portion 4 on electrode 5x and the extending direction of low resistance portion 4 on electrode 5y cross each other. This eases the formation of a grid pattern. In a pattern change, a part with high optical state and a part with low optical state are mixed in the plane, and form a predetermined pattern. Such optical switching device 100 has excellent optical property.

Plurality of optically variable units 1 in optical switching device 100 may be able to be driven independently of each other. The optical property can be enhanced when optically variable unit 1 is independently controllable. The capability of independently driving optically variable unit 1 may be the capability of independently supplying electric power to optically variable unit 1.

Optical switching device 100 may be produced by any appropriate method, such as a method of independently forming each part on a substrate by a stacking process and then bonding the parts together or a method of forming each part on a substrate in sequence from one surface side by a stacking process.

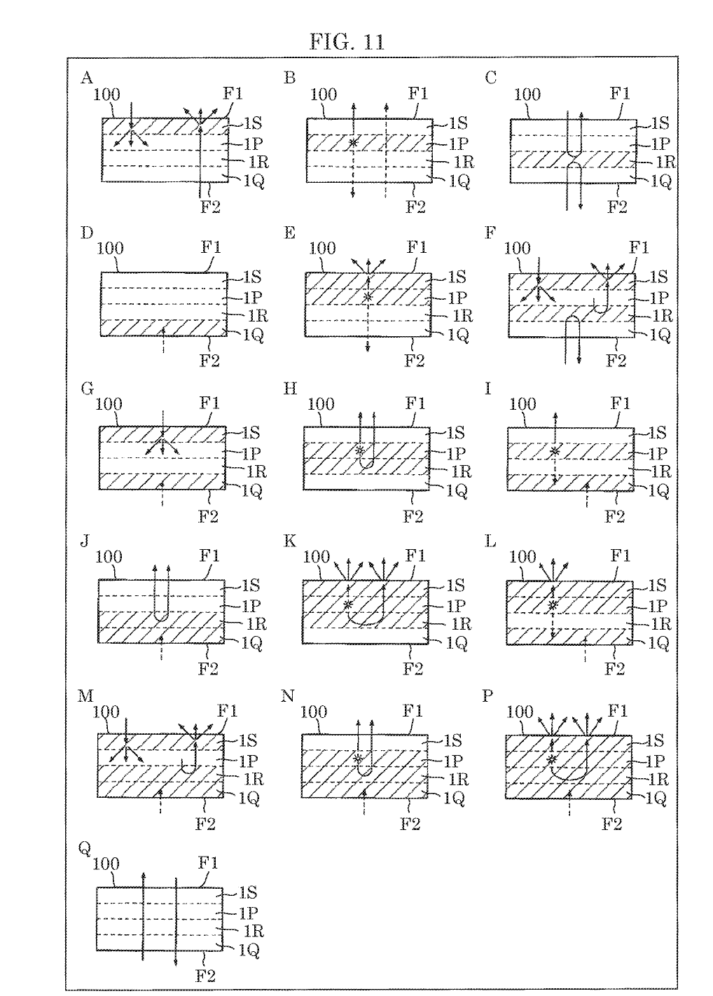

FIG. 11 illustrates examples of the functions of optical switching device 100. Plurality of optically variable units 1 are schematically illustrated in FIG. 11. Each arrow indicates the traveling direction of light. In FIG. 11, light scattering variable unit 1S, planar light emitting unit 1P, light reflection variable unit 1R, and light absorption variable unit 1Q are arranged as plurality of optically variable units 1 from the first surface F1 side as an example. Optical switching device 100 in FIG. 11 is configured to mainly extract light of planar light emitting unit 1P from first surface F1.

In FIG. 11, each functioning optically variable unit 1 is indicated by diagonal lines. The term “functioning” means the state where light scattering is performed in light scattering variable unit 1S, the state where light is emitted in planar light emitting unit 1P, the state where light reflection is performed in light reflection variable unit 1R, or the state where light absorption is performed in light absorption variable unit 1Q. Each optically variable unit 1 not functioning may be transparent. Although no intermediate state of light scattering, light reflection, or light absorption is illustrated for the sake of simplicity, there may be an intermediate state. A to Q in FIG. 11 differ in the states of the functions of optically variable units 1, and optical switching device 100 is in a different state in each of A to Q in FIG. 11. Optical switching device 100 may be capable of all of the states in A to Q in FIG. 11, or may be capable of some of the states in A to Q in FIG. 11. Optical switching device 100 can switch its optical state.

As illustrated in FIG. 11, when at least one of plurality of optically variable units 1 is functioning, light entering optical switching device 100 from outside is unlikely to directly pass through optical switching device 100, and optical switching device 100 may be opaque. For example, in the case where light scattering variable unit 1S performs light scattering as in A in FIG. 11, light is scattered, so that light cannot directly pass through optical switching device 100 between first surface F1 and second surface F2. In the case where light reflection variable unit 1R performs light reflection as in C in FIG. 11, light is reflected, so that light cannot directly pass through optical switching device 100 between first surface F1 and second surface F2. In the case where light absorption variable unit 1Q performs light absorption as in D in FIG. 11, light is absorbed, so that light cannot pass through optical switching device 100 between first surface F1 and second surface F2. Even in the case where planar light emitting unit 1P is functioning as in B in FIG. 11, light emitted from the planar light emitting unit makes the other side less visible, and optical switching device 100 may be opaque. In Q in FIG. 11, on the other hand, no optically variable unit 1 is functioning, and optical switching device 100 is transparent. Thus, optical switching device 100 can change from the transparent state in Q in FIG. 11 to any of the various opaque states in A to P in FIG. 11, and therefore has improved optical property. Particularly when a plurality of optical pattern changes are possible, complex changes are made between opacity and transparency, with it being possible to form a plurality of patterns. Elaborate optical states can be achieved in this way. In FIG. 11, the traveling direction of light is indicated by each arrow. The optical action of optical switching device 100 in each state can be understood from such drawing. The functions of plurality of optically variable units 1 can also be understood from the foregoing Table 1.

While FIG. 11 illustrates an example of combining four optically variable units 1 of different types, the functions of optical switching device 100 in the case where the number of optically variable units 1 is three or two can equally be understood from this example. Moreover, the functions of optical switching device 100 in the case where the arrangement (order) of optically variable units 1 is changed can equally be understood based on FIG. 11.

Optical switching device 100 can be used as a window. A window that creates optically different states may be defined as an active window. A window that changes in pattern between opacity and transparency is very useful. The window may be any of an inner window and an outer window. The window may be a transportation window. The transportation window may be a vehicle window of a car, a train, a locomotive, etc., an airplane window, or a ship window. The window variable between opacity and transparency is, for example, suitable for an expensive car. Optical switching device 100 may also be used as a building material. The building material may be a wall material, a partition, a signage, etc. The signage may be an illuminated advertisement. The wall material may be for an outer wall or an inner wall.

In the case where optical switching device 100 includes the planar light emitting unit, optical switching device 100 can be used as a lighting device. Optical switching device 100 can realize a lighting that varies in pattern.

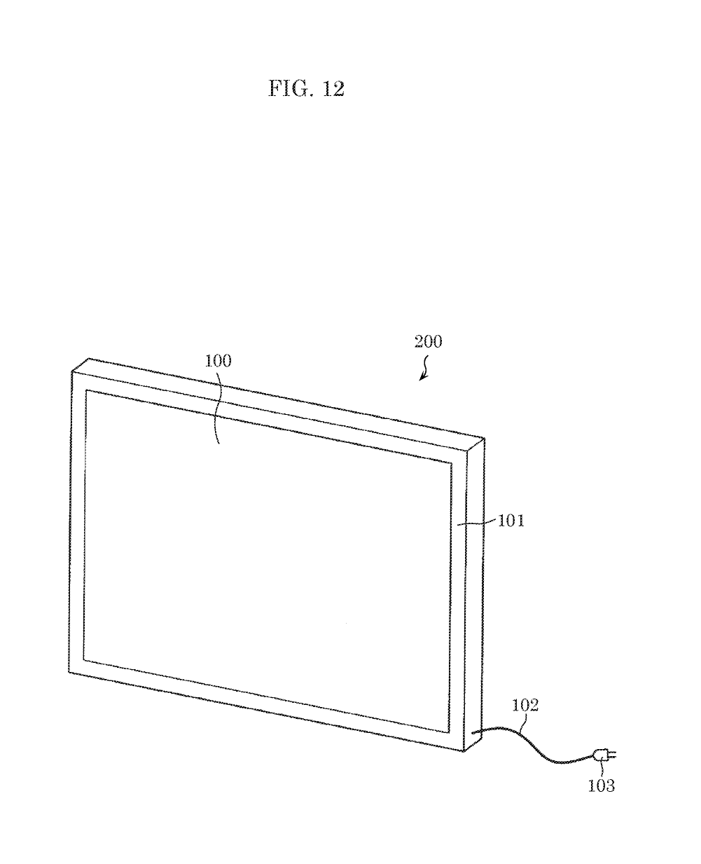

FIG. 12 illustrates an application of optical switching device 100. Building material 200 is illustrated in FIG. 12. Building material 200 in FIG. 12 is a window. Building material 200 includes optical switching device 100. Building material 200 has frame body 101, wiring 102, and plug 103. Building material 200 is an electric building material. Frame body 101 surrounds optical switching device 100. Wiring 102 is electrically connected to optical switching device 100. Plug 103 is connectable to an external power source. When electric power is supplied to optical switching device 100 through plug 103 and wiring 102, the optical state of optical switching device 100 can change. For example, optical switching device 100 changes between a plurality of states such as a transparent state, a translucent (frosted) state, a mirror state, and a light emitting state. Such building material 200 has excellent optical property.

While the optical switching device, the building material, and the like have been described above by way of embodiments, the optical switching device and the like according to the present disclosure are not limited to the above embodiments. Other modifications obtained by applying various changes conceivable by a person skilled in the art to the embodiments and any combinations of the structural elements and functions in different embodiments without departing from the scope of the present disclosure are also included in the scope of one or more aspects.

### REFERENCE MARKS IN THE DRAWINGS

1 optically variable unit

2 optically variable layer

3 power supply terminal

4 low resistance portion

4A auxiliary wiring

4B transparent conductive portion

5 electrode

6 substrate

100 optical switching device

1. An optical switching device comprising:
a plurality of optically variable units that are planar and are variable in a degree of optical transparency according to electric power; and
a plurality of power supply terminals that supply electric power to any of the plurality of optically variable units,
wherein the plurality of optically variable units are arranged in a thickness direction,
each of the plurality of optically variable units has a pair of electrodes,
each of the pair of electrodes in at least one of the plurality of optically variable units is connected to the plurality of power supply terminals, and
the plurality of power supply terminals supply electric power in which at least one of current and voltage is controlled in a plurality of levels.

2. The optical switching device according to claim 1,
wherein each of the pair of electrodes is connected to the plurality of power supply terminals in a different pattern.

3. The optical switching device according to claim 1, comprising
a low resistance portion in contact with at least one of the pair of electrodes and extending in a plane of the optically variable unit,
wherein the low resistance portion electrically connects the plurality of power supply terminals in the plane.

4. The optical switching device according to claim 3,
wherein the low resistance portion is auxiliary wiring.

5. The optical switching device according to claim 3,
wherein the low resistance portion is a transparent conductive portion.

6. The optical switching device according to claim 1,
wherein the plurality of optically variable units include at least an organic electroluminescent element and a light scattering variable unit.

7. A building material comprising:
the optical switching device according to claim 1; and
wiring.
